(19) United States
(12) Patent Application Publication
(10) Pub. No.: US 2026/0317483 A1
(43) Pub. Date: Oct. 15, 2026

(54) Silicone elastomer for dielectric actuators, having prolonged service life

(71) Applicant: WACKER CHEMIE AG, Munich (DE)

(72) Inventor: Andreas Köllnberger, Munich (DE)

(73) Assignee: WACKER CHEMIE AG, Munich (DE)

(21) Appl. No.: 19/484,000

(22) PCT Filed: May 15, 2023
(86) PCT No.: PCT/EP2023/063029

§ 371 Date: Nov. 13, 2025

(51) Int. Cl. C08G 77/20; C08G 77/12; C08K 9/04

(52) U.S. Cl. CPC C08G 77/20; C08G 77/12; C08K 9/04; C08K 2201/006

(57) ABSTRACT

The present invention relates to the use of silicone elastomers obtainable from defined, addition-crosslinking organopolysiloxane compositions in dielectric elastomer actuators (DEAs), which enable DEAs having a significantly extended lifetime in comparison with the prior art.

The present invention relates to the use of silicone elastomers obtainable from defined, addition-crosslinking organopolysiloxane compositions in dielectric elastomer actuators (DEAs), which enable DEAs having a significantly extended lifetime in comparison with the prior art.

The combination of the modulus of elasticity [MPa] and the breakdown field strength [V/μm] has been used to date in the prior art for the characterization, the comparison and the evaluation of dielectric layers or transducers based on electroactive polymers, since the breakdown field strength is a measure of the electrical loading capacity of the dielectric layer and is used as a decisive criterion for the lifetime.

US2015315347A (=corresponding to EP2931792) describes a process for producing thin silicone films which are particularly suitable for applications in the field of dielectric transducers due to a high thickness precision due to the manner of manufacture. Various silicone base materials can be used here.

Described in US2015344671A (=corresponding to EP2938679) are silicones having functional groups which make it possible to increase electrical permittivity. This does increase the energy density of transducers in relation to the layer thickness, however the breakdown voltage and thus the loading capacity is lower than in the case of polydimethylsiloxane-based layers which do not comprise the described groups. The same applies to the lifetime.

US2022017701A (=corresponding to EP3892686) claims specific silicone elastomer mixtures, but without reference to the lifetime of actuators or generators, which additionally have low breakdown field strengths in the range between 54 and 65.4 V/μm.

To date, there is no disclosure whatsoever in the prior art of a correlation between the lifetime and the constituents used.

There continues to be a great need for materials that are suitable for increasing the lifetime of actuators in comparison with the prior art.

The present invention therefore provides silicone-based, dielectric elastomer actuators (DEAs), with an equibiaxial prestretch by a factor of 1.3, measured at a continuously applied DC voltage of 90 V/μm at a temperature of 85° C. and 85% relative humidity, wherein
they comprise a dielectric composed of silicone, which is produced by crosslinking of an addition-crosslinking silicone elastomer composition (X), comprising
   (A1) 20 to 60 wt % of at least one organopolysiloxane with an average molar mass Mw of at most 40 000 g/mol having at least two aliphatically unsaturated radicals per molecule,
   (A2) 1 to 40 wt % of at least one organopolysiloxane with an average molar mass M_{w} of at least 85 000 g/mol having at least two aliphatically unsaturated radicals per molecule,
   (B) 0.1 to 10 wt % of at least one organohydropolysiloxane having at least three silicon-bonded hydrogen atoms,
   (C) 5 to 30 wt % of at least one alkenyl group-containing silicone resin, having at least one branching point,
   (D) at least one hydrosilylation catalyst,
   (E) 5 to 30 wt % of a reinforcing filler with an average surface area between 50 and 400 m²/g,
      with the proviso that
      the sum total of all components always adds up to 100 wt %,
      the Si—H/Si-vinyl ratio of (B) to (A1), (A2), (C) and (E) is selected such that it is between 0.5 and 3 in order to ensure crosslinking, and
      the ratio of (A1) to (A2) is at least 1.5, and therefore (A1)/(A2)≥1.5.

The lifetime was determined under a static electric field at a continuous voltage load of 90 V/μm with different combinations of temperature and humidity. A sample of the elastomer is crosslinked here in a layer that is about 20 μm. The manner of production of this thin layer does not matter; use can be made of all processes known from the prior art, such as spin coating, doctor blade application or slot die application. After production, the samples are equibiaxially stretched by a particular factor (for example 1.3 or 1.7), and an electrically conductive electrode is applied to both sides in order to realize a capacitor-like construction. The electrode may likewise be applied using various methods, for example by means of pad printing. The electrode material consists of conductive particles, for example carbon black or nanoscale carbon fibers. After the prestretching, the elastomer preferably has a thickness in the test between 10 μm and 20 μm.

The figure for the lifetime in [h] is based here on the failure of 50% of the samples (t50% according to Weibull).

A detailed disclosure of this determination method, sample preparation and evaluation can be found in the following technical article: Fabio Beco Albuquerque and Herbert Shea 2021 Smart Mater. Struct. 30 125022. There are various methods for producing thin layers, such as application by means of spin coating, doctor blade, slot die or other techniques known in the prior art.

In order not to create an excessive number of pages in the description of the present invention, only the preferred embodiments of the individual features are specified hereinbelow.

However, the expert reader should explicitly understand this manner of disclosure such that any combination of different levels of preference is thus also explicitly disclosed and explicitly desired.

The silicone-based DEAs according to the invention preferably comprise a dielectric composed of silicone having a thickness of 10 to 100 μm, and a thickness accuracy of ±5%, measured over an area of 200 cm².

The present invention further provides a process for producing silicone-based, dielectric elastomer actuators (DEAs), having a lifetime of at least 30 hours with an equibiaxial prestretch by a factor of 1.3, measured at a continuously applied DC voltage of 90 V/μm at a temperature of 85° C. and 85% relative humidity, wherein the dielectric present is produced by crosslinking of an addition-crosslinking silicone elastomer composition (X), where the silicone elastomer composition (X) comprises
(A1) 20 to 60 wt % of at least one organopolysiloxane with an average molar mass Mw of at most 40 000 g/mol having at least two aliphatically unsaturated radicals per molecule,
(A2) 1 to 40 wt % of at least one organopolysiloxane with an average molar mass Mw of at least 85 000 g/mol having at least two aliphatically unsaturated radicals per molecule,
(B) 0.1 to 10 wt % of at least one organohydropolysiloxane having at least three silicon-bonded hydrogen atoms,
(C) 5 to 30 wt % of at least one alkenyl group-containing silicone resin, having at least one branching point,
(D) at least one hydrosilylation catalyst,
(E) 5 to 30 wt % of a reinforcing filler with an average surface area between 50 and 400 m²/g,
   with the proviso that
   the sum total of all components always adds up to 100 wt %,
   the Si—H/Si-vinyl ratio of (B) to (A1), (A2), (C) and (E) is selected such that it is between 0.5 and 3 in order to ensure crosslinking, and
   the ratio of (A1) to (A2) is at least 1.5, and therefore (A1)/(A2)≥1.5.

For the manufacture of dielectric elastomer actuators (DEAs), thin elastomer layers in the range between 10 μm and 100 μm are first produced from the silicone elastomer compositions (X) according to the invention, these layers serving as a basis for the dielectric. For testing purposes, all technologies are suitable for producing thin layers, such as spin coating, roller application, dip coating, spraying, doctor blade application, box-type doctor blade application or slot die application. For industrial purposes, preference is given to application by doctor blade, chamber doctor blade and slot die, and particular preference to application by chamber doctor blade and slot die. In addition, it is crucial that the silicone elastomer composition (X), depending on the selected layer thickness, does not comprise any particles larger than two thirds of the silicone elastomer layer thickness. In the case of a 30 μm layer, this means that no particles larger than 20 μm should be present. For this layer thickness, the number of particles between 20 and 30 μm in a preferred embodiment is less than 100 ppm and particularly preferably less than 10 ppm.

Due to the required freedom from particles, it must be ensured during the whole process of material and actuator production that the processes are carried out under controlled conditions in relation to the surroundings and the ambient air (filtered air, clean rooms).

The removal of any particles present from the silicone elastomer composition (X) may in principle be performed by all techniques known from the prior art. Examples of such techniques are straining via strainer sieves (wire nets, wire mesh), filter candles made of a very wide variety of materials (metal, plastic, ceramic, etc.), filtration techniques such as magnetic filtration, pressure filtration via filter presses, backflow filters, suction filters, etc. with or without filter aids such as activated carbon, metal oxides, etc. A further example of the removal of particles from the silicone elastomer composition (X) is centrifugation, and all of the methods mentioned or possible may be performed in a batch process or continuously.

The process for producing the elastomer actuators from the silicone elastomer composition (X) is preferably performed under clean-room conditions, in which there are no particles larger than 5 μm. For the design of the production plant, this means that the uncrosslinked silicone composition, after the removal of any particles present, is stored and processed only in clean rooms of ISO 5 (ISO 1466-1) class and better. Preferably in clean rooms of ISO 4 class and better.

The addition-crosslinking silicone elastomer compositions (X) according to the invention may be either one-component silicone compositions or two-component silicone compositions.

In the case of two-component silicone elastomer compositions (X), the two components of the addition-crosslinking silicone elastomer composition (X) according to the invention may comprise all constituents in any desired combination, generally with the proviso that one component does not simultaneously comprise siloxanes having an aliphatic multiple bond, siloxanes having Si-bonded hydrogen and catalyst, i.e. essentially does not simultaneously comprise constituents (A1), (A2), (B), (C), (D) and (E).

### Components (A1) and (A2)

Compounds (A1) and (A2) used in the addition-crosslinking silicone elastomer compositions (X) according to the invention are selected such that (A1) and (A2) have at least two aliphatically unsaturated radicals.

The addition-crosslinking silicone elastomer composition (X) according to the invention usually comprises 20-60 wt %, preferably 25-55 wt % and particularly preferably 30-50 wt % of (A1), and 1-40 wt %, preferably 2-30 wt % and particularly preferably 5-20 wt % of (A2).

The addition-crosslinking silicone elastomer compositions (X) according to the invention preferably comprise, as constituents (A1) and (A2), at least one aliphatically unsaturated organosilicon compound, it being possible to use all aliphatically unsaturated organosilicon compounds used to date in addition-crosslinking compositions, such as silicone block copolymers having urea segments, silicone block copolymers having amide segments and/or imide segments and/or ester amide segments and/or polystyrene segments and/or silarylene segments and/or carborane segments and silicone graft copolymers having ether groups.

Organosilicon compounds (A1) or (A2) used that comprise SiC-bonded radicals having aliphatic carbon-carbon multiple bonds are preferably linear or branched organopolysiloxanes composed of units of the general formula (I)

R¹ₐR²_{b}SiO_{(4-a-b)/2} (I)
where
   R¹ independently at each occurrence is identical or different and is an organic or inorganic radical free of aliphatic carbon-carbon multiple bonds,
   R² independently at each occurrence is identical or different and is a monovalent, substituted or unsubstituted, SiC-bonded hydrocarbon radical having at least one aliphatic carbon-carbon multiple bond,
   a is 0, 1, 2 or 3, and
   b is 0, 1 or 2,
with the proviso that the sum total of a+b is less than or equal to 3 and there are at least 2 radicals R² per molecule.

Radical R¹ may be mono- or polyvalent radicals, where the polyvalent radicals, such as bivalent, trivalent and tetravalent radicals, then connect multiple, for instance two, three or four, siloxy units of the formula (I) to one another.

Further examples of R¹ are the monovalent radicals —F, —Cl, —Br, OR⁶, —CN, —SCN, —NCO and SiC-bonded, substituted or unsubstituted hydrocarbon radicals which may be interrupted by oxygen atoms or the group-C(O)—, and divalent radicals Si-bonded at both ends as per formula (I). If radical R¹ is SiC-bonded, substituted hydrocarbon radicals, preferred substituents are halogen atoms, phosphorus-containing radicals, cyano radicals, —OR⁶, —NR⁶—, —NR⁶₂, —NR⁶—C(O)—NR⁶₂, —C(O)—NR⁶₂, —C(O)R⁶, —C(O)OR⁶, —SO₂-Ph and —C₆F₅. In this case, R⁶ is independently at each occurrence identical or different and is a hydrogen atom or a monovalent hydrocarbon radical having 1 to 20 carbon atoms and Ph is the phenyl radical.

Examples of radicals R¹ are alkyl radicals, such as the methyl, ethyl, n-propyl, isopropyl, n-butyl, isobulyl, tert-butyl, n-pentyl, isopentyl, neopentyl, tert-pentyl radical, hexyl radicals, such as the n-hexyl radical, heptyl radicals, such as the n-heptyl radical, octyl radicals, such as the n-octyl radical, and isooctyl radicals, such as the 2,2,4-trimethylpentyl radical, nonyl radicals, such as the n-nonyl radical, decyl radicals, such as the n-decyl radical, dodecyl radicals, such as the n-dodecyl radical, and octadecyl radicals, such as the n-octadecyl radical, cycloalkyl radicals, such as cyclopentyl, cyclohexyl, cycloheptyl and methylcyclohexyl radicals, aryl radicals, such as the phenyl, naphthyl, anthryl and phenanthryl radical, alkaryl radicals, such as o-, m-, p-tolyl radicals, xylyl radicals and ethylphenyl radicals, and aralkyl radicals, such as the benzyl radical, the α- and the β-phenylethyl radical.

Examples of substituted radicals R¹ are haloalkyl radicals, such as the 3,3,3-trifluoro-n-propyl radical, the 2,2,2,2′,2′,2′-hexafluoroisopropyl radical, the heptafluoroisopropyl radical, haloaryl radicals, such as the o-, m- and p-chlorophenyl radical, —(CH₂)—N(R⁶)C(O)NR⁶₂, —(CH₂)ₒ—C(O)NR⁶₂, —(CH₂)ₒ—C(O)R⁶, —(CH₂)ₒ—C(O)OR⁶, —(CH₂)ₒ—C(O)NR⁶₂, —(CH₂)—C(O)—(CH₂)ₚC(O)CH₃, —(CH₂)—O—CO—R⁶, —(CH₂)—NR⁶—(CH₂)ₚ—NR⁶₂, —(CH₂)ₒ—O—(CH₂)ₚCH(OH)CH₂OH, —(CH₂)(OCH₂CH₂)ₚOR⁶, —(CH₂)ₒ—SO₂-Ph and —(CH₂)ₒ—O—C₆F₅, where R⁶ and Ph correspond to the definition given for them above and o and p are identical or different integers between 0 and 10.

Examples of R¹ as divalent radicals Si-bonded at both ends as per formula (I) are those that derive from the monovalent examples given above for radical R¹ in that there is an additional bond through substitution of a hydrogen atom; examples of such radicals are —(CH₂)—, —CH(CH₃)—, —C(CH₃)₂—, —CH(CH₃)—CH₂—, —C₆H₄—, —CH(Ph)-CH₂—, —C(CF₃)₂—, —(CH₂)ₒ—C₆H₄—(CH₂)ₒ—, —(CH₂)ₒ—C₆H₄—C₆H₄—(CH₂)ₒ—, —(CH₂O)ₚ, (CH₂CH₂O)ₒ, —(CH₂)ₒ—Oₓ—C₆H₄—SO₂—C₆H₄—Oₓ—(CH₂)ₒ—, where x is 0 or 1, and Ph, o and p have the definition given above.

Radical R¹ is preferably a monovalent, SiC-bonded, optionally substituted hydrocarbon radical that is free of aliphatic carbon-carbon multiple bonds and has 1 to 18 carbon atoms, particularly preferably a monovalent, SiC-bonded hydrocarbon radical that is free of aliphatic carbon-carbon multiple bonds and has 1 to 6 carbon atoms, in particular the methyl or phenyl radical.

Radical R² may be any desired group that is amenable to an addition reaction (hydrosilylation) with an SiH-functional compound.

If radical R² is SiC-bonded, substituted hydrocarbon radicals, preferred substituents are halogen atoms, cyano radicals and —OR⁶, where R⁶ has the definition given above.

Radical R² is preferably alkenyl and alkynyl groups having 2 to 16 carbon atoms, such as vinyl, allyl, methallyl, 1-propenyl, 5-hexenyl, ethynyl, butadienyl, hexadienyl, cyclopentenyl, cyclopentadienyl, cyclohexenyl, vinylcyclohexylethyl, divinylcyclohexylethyl, norbornenyl, vinylphenyl and styryl radicals, particular preference being given to the use of vinyl, allyl and hexenyl radicals.

The molecular weight M_{w} of constituent (A1) should on average be at most 40 000 g/mol; the molecular weight M_{w} of constituent (A2) should on average be greater than 85 000 g/mol. M_{w} here means the mass-average molar mass. (A1) has a preferred average molar mass M_{w} of at most 30 000 g/mol and particularly preferably of at most 20 000 g/mol. (A2) has a preferred average molar mass M_{w} of at least 90 000 g/mol and particularly preferably of at least 95 000 g/mol.

For example, constituents (A1) and (A2) may thus be an alkenyl-functional oligo- or polysiloxane, also a high-polymeric polydimethylsiloxane having Si-bonded vinyl groups in chain or terminal positions (number average determined by means of NMR). The structure of the molecules forming constituents (A1) and (A2) is not fixed; in particular, the structure of a siloxane of relatively high molecular weight, i.e. an oligomeric or polymeric siloxane, may be linear, cyclic, branched or else resinous, network-like. Linear and cyclic polysiloxanes are preferably composed of units of the formula R¹₃SiO_{1/2}, R²R¹₂SiO_{1/2}, R²R¹SiO_{1/2} and R¹₂SiO_{2/2}, where R¹ and R² have the definition given above. Branched and network-like polysiloxanes additionally comprise trifunctional and/or tetrafunctional units, preference being given to those of the formulae R¹SiO_{3/2}, R²SiO_{3/2} and SiO_{4/2}. It is of course also possible to use mixtures of different siloxanes that meet the criteria of constituents (A1) and (A2).

Particularly preferred as components (A1) and (A2) is the use of vinyl-functional, essentially linear polydiorganosiloxanes having the molecular weights specified.

### Component (B)

Organosilicon compound (B) used may be all hydrogen-functional organosilicon compounds that have also been used to date in addition-crosslinkable compositions.

The addition-crosslinking silicone elastomer composition (X) according to the invention usually comprises 0.1 to 10 wt % of (B), preferably 1-8 wt % of (B) and particularly preferably 2-7 wt % of (B).

Organopolysiloxanes (B) used that have Si-bonded hydrogen atoms are preferably linear, cyclic or branched organopolysiloxanes composed of units of the general formula (III)

R¹_{c}H_{d}SiO_{(4-c-d)/2} (III)
where
   R¹ has the definition given above,
   c is 0, 1, 2 or 3 and
   d is 0, 1 or 2,
with the proviso that the sum total of c+d is less than or equal to 3 and there are at least two Si-bonded hydrogen atoms per molecule.

The organopolysiloxane (B) used according to the invention preferably comprises Si-bonded hydrogen in the range from 0.04 to 1.7 percent by weight (wt %), based on the total weight of the organopolysiloxane (B).

The molecular weight of constituent (B) may vary within wide limits, for instance between 102 and 106 g/mol. For example, constituent (B) may thus be an SiH-functional oligosiloxane of relatively low molecular weight, such as tetramethyldisiloxane, but also a high-polymeric polydimethylsiloxane having SiH groups in chain or terminal positions or a silicone resin having SiH groups.

The structure of the molecules forming constituent (B) is not fixed either; in particular, the structure of an SiH-containing siloxane of relatively high molecular weight, i.e. an oligomeric or polymeric SiH-containing siloxane, may be linear, cyclic, branched or else resinous, network-like. Linear and cyclic polysiloxanes (B) are preferably composed of units of the formula R¹₃SiO_{1/2}, HR¹₂SiO_{1/2}, HR¹SiO_{2/2} and R¹₂SiO_{2/2}, where R¹ has the definition given above. Branched and network-like polysiloxanes additionally comprise trifunctional and/or tetrafunctional units, preference being given to those of the formulae R¹SiO_{3/2}, HSiO_{3/2} and SiO_{4/2}, where R¹ has the definition given above.

It is of course also possible to use mixtures of different siloxanes that meet the criteria of constituent (B). Particularly preferred is the use of SiH-functional compounds of low molecular weight such as tetrakis(dimethylsiloxy) silane and tetramethylcyclotetrasiloxane, and SiH-containing siloxanes of relatively high molecular weight, such as poly(hydrogenmethyl) siloxane and poly(dimethylhydrogenmethyl) siloxane, having a viscosity at 25° C. of 10 to 20 000 mPa·s (shear d=1 s⁻¹), or analogous SiH-containing compounds in which some of the methyl groups have been replaced by 3,3,3-trifluoropropyl or phenyl groups.

To set the mechanical properties of the cured silicone film, α,ω-Si—H-functional polyorganosiloxanes with a dynamic viscosity of 10-100 000 mPa·s (shear d=1 s⁻¹) may preferably be used as (B).

Constituent (B) is preferably present in the crosslinkable silicone compositions (X) according to the invention in such an amount that the molar ratio of SiH groups to aliphatically unsaturated groups from (A) is 0.5 to 3, particularly preferably between 0.8 and 2.0.

Components (A1), (A2) and (B) used according to the invention are commercially available products or can be produced by standard chemical methods.

### Constituent (C):

Constituents (C) used are resins selected from:
MQ siloxane resins, constructed from M units of the formula R⁹₃SiO_{1/2} and Q units of the formula SiO_{4/2},
MT siloxane resins, constructed from M units of the formula R⁹₃SiO_{1/2} and T units of the formula R⁹SiO_{3/2}, and
MTQ siloxane resins, constructed from of the formula R⁹₃SiO_{1/2} and T units of the formula R⁹SiO_{3/2} and Q units of the formula SiO_{4/2}
or a mixtures of two or more of such resins,
where
R⁹ are saturated hydrocarbon radicals that are optionally substituted by halogens and have 1-40 carbon atoms, and where at least 2 of the radicals R per molecule are alkenyl radicals having 1-10 carbon atoms.

Preferably at least 0.1 mol %, particularly preferably at least 0.5 mol %, in particular at least 2 mol %, and preferably at most 20 mol %, in particular at most 10 mol %, of the radicals R⁹ are alkenyl radicals having 1-10 carbon atoms.

The hydrocarbon radicals R⁹ may be halogen-substituted, linear, cyclic, branched, aromatic, saturated or unsaturated.

Examples of unsubstituted radicals R⁹ are alkyl radicals, such as the methyl, ethyl, n-propyl, isopropyl, n-butyl, isobutyl, tert-butyl, n-pentyl, isopentyl, neopentyl, tert-pentyl radical, hexyl radicals, such as the n-hexyl radical, heptyl radicals, such as the n-heptyl radical, octyl radicals, such as the n-octyl radical, and isooctyl radicals, such as the 2,2,4-trimethylpentyl radical, nonyl radicals, such as the n-nonyl radical, decyl radicals, such as the n-decyl radical; cycloalkyl radicals, such as cyclopentyl, cyclohexyl, 4-ethylcyclohexyl, cycloheptyl radicals, norbornyl radicals and methylcyclohexyl radicals; aryl radicals, such as the phenyl, biphenylyl, naphthyl radical; alkaryl radicals, such as o-, m-, p-tolyl radicals and ethylphenyl radicals; aralkyl radicals, such as the benzyl radical, the alpha- and the β-phenylethyl radical.

Examples of substituted hydrocarbon radicals as radicals R⁹ are halogenated hydrocarbons, such as the chloromethyl, 3-chloropropyl, 3-bromopropyl, 3,3,3-trifluoropropyl and 5,5,5,4,4,3,3-hexafluoropentyl radical, and the chlorophenyl, dichlorophenyl and trifluorotolyl radical.

The hydrocarbon radicals R⁹ preferably have 1 to 6 carbon atoms, and particularly preferably are alkyl radicals and phenyl radicals. Preferred halogen substituents are fluorine and chlorine. Particularly preferred monovalent hydrocarbon radicals R⁹ are methyl, ethyl and phenyl.

The alkenyl groups R⁹ are amenable to an addition reaction with the SiH-functions of component (B). Use is usually made of alkenyl groups having 2 to 6 carbon atoms, such as vinyl, allyl, methallyl, 1-propenyl, 5-hexenyl, ethynyl, butadienyl, hexadienyl, cyclopentenyl, cyclopentadienyl, cyclohexenyl, preferably vinyl and allyl.

The addition-crosslinking silicone elastomer composition (X) according to the invention usually comprises 5 to 30 wt % of (C), preferably 6 to 30 wt %, more preferably 7 to 25 wt % of (C) and particularly preferably 7 to 15 wt % of (C).

### Constituent D

Hydrosilylation catalysts (D) used may be all catalysts known from the prior art. Component (D) may be a platinum group metal, for example platinum, rhodium, ruthenium, palladium, osmium or iridium, an organometallic compound or a combination thereof. Examples of component (D) are compounds such as hexachloroplatinum (IV) acid, platinum dichloride, platinum acetylacetonate and complexes of said compounds encapsulated in a matrix or a core/shell-type structure. The platinum complexes with low molecular weight of the organopolysiloxanes include 1,3-diethenyl-1,1,3,3-tetramethyldisiloxane complexes with platinum. Further examples are platinum-phosphite complexes or platinum-phosphine complexes. For light- or UV-curing compositions, use may for example be made of alkyl-platinum complexes such as derivatives of cyclopentadienyltrimethylplatinum (IV), cyclooctadienyldimethylplatinum (II), or diketonato complexes such as bisacetylacetonatoplatinum (II), in order to initiate the addition reaction by means of light. These compounds may be encapsulated in a resin matrix.

The concentration of component (D) is sufficient for catalyzing the hydrosilylation reaction of components (A1), (A2) and (B) and (C) on contact, in order to produce the heat required here in the process described. The amount of component (D) may be between 0.1 and 1000 parts per million (ppm), 0.5 and 100 ppm or 1 and 25 ppm of the platinum group metal, depending on the total weight of the components. The curing rate may be low if the constituent of the platinum group metal is below 1 ppm. The use of more than 100 ppm of the platinum group metal is uneconomic or lowers the storage stability of the silicone elastomer composition (X).

### Constituent (E)

Reinforcing fillers (E) are a further constituent of the addition-crosslinking silicone compositions (X). Fumed or precipitated silicas having BET surface areas between 50 m²/g and 400 m²/g are preferred, with preference being given to fumed and precipitated silicas having BET surface areas between 100 m²/g and 200 m²/g. The silica fillers mentioned may have hydrophilic character or be hydrophobized by known methods. The content of actively reinforcing filler in the crosslinkable silicone elastomer composition (X) according to the invention is in the range from 5 to 30 wt %, preferably 10 to 25 wt %.

Particularly preferably, the crosslinkable addition-crosslinking silicone elastomer compositions (X) are characterized in that the filler (E) is surface-treated. The surface treatment is achieved by the processes known in the prior art for hydrophobizing finely divided fillers.

As a result of a surface treatment, preferred fillers (E) have a carbon content of at least 0.01 to at most 20 wt %, preferably between 0.1 and 10 wt %, particularly preferably between 0.5 and 5 wt %. Particular preference is given to crosslinkable addition-crosslinking silicone elastomer compositions (X) that are characterized in that the filler (E) is a surface-treated silica, having 0.01 to 2 wt % of Si-bonded, aliphatically unsaturated groups. By way of example, these are Si-bonded vinyl groups. In the addition-crosslinking silicone compositions (X) according to the invention, constituent (E) is preferably used as an individual filler or likewise preferably as a mixture of several finely divided fillers.

The addition-crosslinking silicone elastomer composition (X) according to the invention usually comprises 5 to 30 wt % of (E), preferably 7-25 wt % of (E) and particularly preferably 10-20 wt % of (E).

### Constituent (F)

The addition-crosslinking silicone elastomer composition (X) according to the invention may optionally comprise, as constituents, further additions at a proportion of up to 70 wt %, preferably 0.0001 to 40 wt %. These additions may for example be inactive fillers, resinous polyorganosiloxanes different from the siloxanes (A1), (A2), (B) and (C), non-reinforcing fillers, fungicides, fragrances, rheological additives, corrosion inhibitors, oxidation inhibitors, light stabilizers, flame retardants and agents for influencing the electrical properties, dispersing aids, solvents, adhesion promoters, pigments, dyes, plasticizers, organic polymers, heat stabilizers etc. These include additions such as quartz flour, diatomaceous earth, clays, chalk, lithopone, carbon blacks, graphite, metal oxides, metal carbonates, metal sulfates, metal salts of carboxylic acids, metal dusts, fibers, such as glass fibers, polymer fibers, polymer powders, metal dusts, dyes, pigments etc.

These constituents (F) may additionally be thermally conductive or electrically conductive. Examples of thermally conductive fillers are aluminum nitride; aluminum oxide; barium titanate; beryllium oxide; boron nitride; diamond; graphite; magnesium oxide; particulate metal such as copper, gold, nickel or silver; silicon carbide; tungsten carbide; zinc oxide and a combination thereof. Thermally conductive fillers are known in the prior art and are commercially available. For example, CB-A20S and Al-43-Me are aluminum oxide fillers in different particle sizes that are commercially available from Showa-Denko, and AA-04, AA-2 and AAI 8 are aluminum oxide fillers that are commercially available from Sumitomo Chemical Company. Silver fillers are commercially available from Metalor Technologies U.S.A. Corp. of Attleboro, Massachusetts, U.S.A. Boron nitride fillers are commercially available from Advanced Ceramics Corporation, Cleveland, Ohio, U.S.A. The reinforcing fillers include silica and short fibers such as Kevlar® short fibers. It is possible to use a combination of fillers having different particle sizes and different particle size distribution.

The examples of further optional components (F) include one or more solvents and one or more inhibitors. It should however be ensured that the solvent (F) does not have any adverse effects on the overall system. Suitable solvents (F) are known in the prior art and are commercially available. The solvent (F) may for example be an organic solvent having 3 to 20 carbon atoms. The examples of solvents (F) include aliphatic hydrocarbons such as nonane, decalin and dodecane; aromatic hydrocarbons such as mesitylene, xylene and toluene; esters such as ethyl acetate and butyrolactone; ethers such as n-butyl ether and polyethylene glycol monomethyl ester; ketones such as methyl isobutyl ketone and methyl pentyl ketone; silicone fluid such as linear, branched and cyclic polydimethylsiloxanes, and combinations of these solvents (F). The optimal concentration of a particular solvent (F) in the addition-crosslinking silicone elastomer composition (X) can easily be determined by routine tests. Depending on the weight of the compound, the amount of solvent (F) may be between 0 and 95 wt % or between 1 and 95 wt %.

The addition-crosslinking silicone elastomer composition (X) may additionally optionally comprise inhibitors and stabilizers. Inhibitors and stabilizers serve to control the processing time, initiation temperature and crosslinking rate of the addition-crosslinking silicone composition (X) according to the invention in a targeted manner. These inhibitors and stabilizers are very well known in the field of addition-crosslinking compositions. Examples of commonly used inhibitors are acetylenic alcohols, such as 1-ethynyl-1-cyclohexanol, 2-methyl-3-butyn-2-ol and 3,5-dimethyl-1-hexyn-3-ol, 3-methyl-1-dodecyn-3-ol, polymethylvinylcyclosiloxanes such as 1,3,5,7-tetravinyltetramethyltetracyclosiloxane, low molecular weight silicone oils having methylvinyl-SiO_{1/2} groups and/or R₂vinylSiO_{1/2} end groups, such as divinyltetramethydisiloxane, tetravinyldimethyldisiloxane, trialkyl cyanurates, alkyl maleates, such as diallyl maleates, dimethyl maleate and diethyl maleate, alkyl fumarates, such as diallyl fumarate and diethyl furmarate, organic hydroperoxides such as cumene hydroperoxide, tert-butyl hydroperoxide and pinane hydroperoxide, organic peroxides, organic sulfoxides, organic amines, diamines and amides, phosphines and phosphites, nitriles, triazoles, diaziridines and oximes. The effect of these inhibitor additions depends on their chemical structure, and so the concentration has to be determined individually. Inhibitors and inhibitor mixtures are preferably added in a proportion of 0.00001 wt % to 5 wt %, based on the total weight of the mixture, preferably 0.00005 to 2 wt % and particularly preferably 0.0001 to 1 wt %.

Activation for the crosslinking may be effected thermally, via IR radiation or via UV radiation. In the case of room-temperature-crosslinking systems, room temperature is sufficient for curing, and so there is no need for an additional supply of energy. Microwave activation or activation by ultrasound is also possible.

In the case of UV-crosslinking systems, the catalyst (D) of the hydrosilylation reaction of the addition-crosslinking silicone elastomer composition (X) is activated by irradiation in order to achieve crosslinking. Use may be made of all light sources known in the prior art, such as LEDs, mercury-vapor lamps, doped mercury-vapor lamps, xenon lamps, or lasers. Wavelengths between 250 and 800 nm are preferably irradiated, particular preference being given to wavelengths between 300 and 500 nm. The arrangement of the light sources is arbitrary, it being possible for the distance between the light source and the silicone composition (X) to be crosslinked to vary between a few millimeters and several centimeters.

Compared with the prior art, the silicone films and dielectrics produced with the described silicone elastomer composition (X) according to the invention have the advantage that EAPs equipped therewith exhibit a lifetime that is longer at least by a factor of 1.2.

In thin layers smaller than 100 μm, the silicone elastomers produced from the silicone elastomer compositions (X) according to the invention further have the advantage that their breakdown voltage in generators and actuators is at least 70 V/μm, preferably at least 80 V/μm and particularly preferably at least 90 V/μm, that is to say significantly better than dielectric electroactive polymers according to the prior art.

Particularly in the applications as EAPs in the field of actuators or generators, the elastomers used are under a great load since several million oscillation cycles are passed through in the course of their lifetime. A further advantage of the silicone elastomers produced from the silicone compositions (X) according to the invention is a very high long-term load resistance.

### EXAMPLES

In the examples described below, all figures for parts and percentages, unless stated otherwise, are based on the weight. Unless stated otherwise, the examples below are conducted at a pressure of the surrounding atmosphere, i.e. at about 1000 hPa, and at room temperature, i.e. at 25° C., or at a temperature which is established on combination of the reactants at room temperature without additional heating or cooling. All viscosity figures hereinafter are based on a temperature of 25° C. The examples below elucidate the invention without having any limiting effect.

The following abbreviations are used:
Ex. example
No. number
Time t
Hour h
RH relative humidity
PDMS polydimethylsiloxane
wt % percent by weight, w/w

The lifetime was determined under a static electric field at a continuous voltage load of 90 V/μm with different combinations of temperature and humidity. A sample of the elastomer is crosslinked here in a layer that is about 20 μm. The manner of production of this thin layer does not matter; use can be made of all processes known from the prior art, such as spin coating, doctor blade application or slot die application. After production, the samples are equibiaxially stretched by a particular factor (for example 1.3 or 1.7), and an electrically conductive electrode is applied to both sides in order to realize a capacitor-like construction. The electrode may likewise be applied using various methods, for example by means of pad printing. The electrode material consists of conductive particles, for example carbon black or nanoscale carbon fibers. After the prestretching, the elastomer preferably has a thickness in the test between 10 μm and 20 μm.

The figure for the lifetime in [h] is based here on the failure of 50% of the samples (t50% according to Weibull).

### Silicone Formulation 1 (Comparative Example 1)

Constituent A: 50 wt % of a linear, vinyl-terminated organopolysiloxane with an average molar mass of 16 500 g/mol

Constituent B: 27 wt % of a linear, Si—H-terminated organopolysiloxane and 3.0 wt % of an Si—H comb crosslinker

Constituent D: 10 ppm based on the metal of a Karstedt-type platinum catalyst

Constituent E: 20 wt % of a hydrophobic, pretreated silica with a BET surface area of 130 m²/g

The ratio of Si-bonded hydrogen atoms to Si-bonded alkylene groups is 1.1.

### Silicone formulation 2 (Comparative Example 2)

Constituent A1:49 wt % of a linear, vinyl-terminated organopolysiloxane with an average molar mass of 16 500 g/mol

Constituent A2:14 wt % of a linear, vinyl-terminated organopolysiloxane with an average molar mass of 70 500 g/mol

Constituent B: 23 wt % of a linear, Si—H-terminated organopolysiloxane and 3.0 wt % of an Si—H comb crosslinker

Constituent C: 4 wt % of a silicone resin comprising M and Q units, where some of the M groups bear a vinyl group,

Constituent D: 10 ppm based on the metal of a Karstedt-type platinum catalyst

Constituent E: 20 wt % of a hydrophobic, pretreated silica with a BET surface area of 130 m²/g

The ratio of Si-bonded hydrogen atoms to Si-bonded alkylene groups is 1.1.

### Silicone Formulation 3 (According to the Invention)

Constituent A1:38 wt % of a linear, vinyl-terminated organopolysiloxane with an average molar mass of 16 500 g/mol

Constituent A2:6 wt % of a linear, vinyl-terminated organopolysiloxane with an average molar mass of 90 000 g/mol

Constituent B: 26 wt % of a linear, Si—H-terminated organopolysiloxane and 5.0 wt % of an Si—H comb crosslinker

Constituent C: 7.0 wt % of a silicone resin comprising M and Q units, where some of the M groups bear a vinyl group.

Constituent D: 10 ppm based on the metal of a Karstedt-type platinum catalyst Constituent E: 18 wt % of a hydrophobic, pretreated silica with a BET surface area of 130 m²/g

The ratio of Si-bonded hydrogen atoms to Si-bonded alkylene groups is 1.1.

### Silicone Formulation 4 (According to the Invention)

Constituent A1:31 wt % of a linear, vinyl-terminated organopolysiloxane with an average molar mass of 16 500 g/mol

Constituent A2:18 wt % of a linear, vinyl-terminated organopolysiloxane with an average molar mass of 95 000 g/mol

Constituent B: 18 wt % of a linear, Si—H-terminated organopolysiloxane and 5.0 wt % of an Si—H comb crosslinker

Constituent C: 8.0 wt % of a silicone resin comprising M and Q units, where some of the M groups bear a vinyl group.

Constituent D: 10 ppm based on the metal of a Karstedt-type platinum catalyst

Constituent E: 20 wt % of a hydrophobic, pretreated silica with a BET surface area of 130 m²/g

The ratio of Si-bonded hydrogen atoms to Si-bonded alkylene groups is 1.1.

### Silicone Formulation 5 (According to the Invention)

Constituent A1:19 wt % of a linear, vinyl-terminated organopolysiloxane with an average molar mass of 16 500 g/mol

Constituent A2:14 wt % of a linear, vinyl-terminated organopolysiloxane with an average molar mass of 110 000 g/mol

Constituent B: 16 wt % of a linear, Si—H-terminated organopolysiloxane and 5.0 wt % of an Si—H comb crosslinker

Constituent C: 10.0 wt % of a silicone resin comprising M and Q units, where some of the M groups bear a vinyl group.

Constituent D: 10 ppm based on the metal of a Karstedt-type platinum catalyst

Constituent E: 18 wt % of a hydrophobic, pretreated silica with a BET surface area of 130 m²/g

The ratio of Si-bonded hydrogen atoms to Si-bonded alkylene groups is 1.1.

TABLE 1
Lifetime at 20° C., 90% RH and 90 V/μm operating voltage

| | | | Factor with | |
|---|---|---|---|---|
| Silicone | t_{50%} | | respect to the | |
| formulation | Lifetime | | reference | Remark |
| 1 | 1 | h | 1 | Comparative Example |
| 2 | 1.2 | h | 1.2 | Comparative Example |
| 3 | 15 | h | 15 | |
| 4 | 21 | h | 21 | |
| 5 | 20 | h | 20 | |

TABLE 2
Lifetime at 20° C., 30% RH and 100 V/μm operating voltage

| | | | Factor with | |
|---|---|---|---|---|
| Silicone | t_{50%} | | respect to the | |
| formulation | Lifetime | | reference | Remark |
| 1 | 110 | h | 1 | Comparative Example |
| 2 | 130 | h | 1.2 | Comparative Example |
| 3 | >1000 | h | >9.1 | |
| 4 | >1000 | h | >9.1 | |
| 5 | >1000 | h | >9.1 | |

TABLE 3
Lifetime at 85° C., 85% RH and 100 V/μm operating voltage

| | | | Factor with | |
|---|---|---|---|---|
| Silicone | t_{50%} | | respect to the | |
| formulation | Lifetime | | reference | Remark |
| 1 | 0.1 | h | 1 | Comparative Example |
| 2 | 0.15 | h | 1.5 | Comparative Example |
| 3 | 1.8 | h | 18 | |
| 4 | 2 | h | 20 | |
| 5 | 2.1 | h | 21 | |

1-7. (canceled)

8. A silicone-based, dielectric elastomer actuator (DEA), having a lifetime of at least 30 hours with an equibiaxial prestretch by a factor of 1.3, measured at a continuously applied DC voltage of 90 V/μm and at a temperature of 85° C. and 85% relative humidity, wherein
the actuator comprises a dielectric composed of silicone, which is produced by crosslinking of an addition-crosslinking silicone elastomer composition (X), comprising
(A1) 20 to 60 wt % of at least one organopolysiloxane with an average molar mass M_{w} of at most 40 000 g/mol having at least two aliphatically unsaturated radicals per molecule,
(A2) 1 to 40 wt % of at least one organopolysiloxane with an average molar mass M_{w} of at least 85 000 g/mol having at least two aliphatically unsaturated radicals per molecule,
(B) 0.1 to 10 wt % of at least one organohydropolysiloxane having at least three silicon-bonded hydrogen atoms,
(C) 5 to 30 wt % of at least one alkenyl group-containing silicone resin, having at least one branching point,
(D) at least one hydrosilylation catalyst,
(E) 5 to 30 wt % of a reinforcing filler with an average surface area between 50 and 400 m²/g,
with the proviso that
the sum total of all components always adds up to 100 wt %,
the Si—H/Si-vinyl ratio of (B) to (A1), (A2), (C) and (E) is selected such that it is between 0.5 and 3 in order to ensure crosslinking, and
the ratio of (A1) to (A2) is at least 1.5, and therefore (A1)/(A2)≥1.5.

9. The silicone-based, dielectric elastomer actuator as claimed in claim 8, where the dielectric composed of silicone has a thickness of 10 to 100 μm, and a thickness accuracy of ±5%, measured over an area of 200 cm².

10. The silicone-based, dielectric elastomer actuator as claimed in claim 8, where at least one α,ω-Si—H-functional polyorganosiloxane with a dynamic viscosity of 10-100 000 mPa·s (d=1 s⁻¹) is present as (B).

11. The silicone-based, dielectric elastomer actuator as claimed in claim 8, where (A1) has an average molar mass Mw of at most 30 000 g/mol and (A2) of at least 85 000 g/mol.

12. A process for producing a silicone-based, dielectric elastomer actuator, having a lifetime of at least 30 hours with an equibiaxial prestretch by a factor of 1.3, measured at a continuously applied DC voltage of 90 V/μm at a temperature of 85° C. and 85% relative humidity, wherein
the dielectric present is produced by crosslinking of an addition-crosslinking silicone elastomer composition (X), where the silicone elastomer composition (X) comprises
(A1) 20 to 60 wt % of at least one organopolysiloxane with an average molar mass M_{w} of at most 40 000 g/mol having at least two aliphatically unsaturated radicals per molecule,
(A2) 1 to 40 wt % of at least one organopolysiloxane with an average molar mass M_{w} of at least 85 000 g/mol having at least two aliphatically unsaturated radicals per molecule,
(B) 0.1 to 10 wt % of at least one organohydropolysiloxane having at least three silicon-bonded hydrogen atoms,
(C) 5 to 30 wt % of at least one alkenyl group-containing silicone resin, having at least one branching point,
(D) at least one hydrosilylation catalyst,
(E) 5 to 30 wt % of a reinforcing filler with an average surface area between 50 and 400 m²/g,
with the proviso that
the sum total of all components always adds up to 100 wt %,
the Si—H/Si-vinyl ratio of (B) to (A1), (A2), (C) and (E) is selected such that it is between 0.5 and 3 in order to ensure crosslinking, and
the ratio of (A1) to (A2) is at least 1.5, and therefore (A1)/(A2)≥1.5.

13. The process as claimed in claim 12, wherein the DEA is manufactured from thin elastomer layers in the range between 10 μm and 100 μm which are produced from the silicone elastomer compositions (X) according to the invention by means of application by doctor blade, chambered doctor blade and slot die.

14. The process as claimed in claim 12, wherein the 10 μm to 100 μm-thin elastomer layers are produced by means of application by chambered doctor blade and slot die.
